(19) United States
(12) Patent Application Publication
(10) Pub. No.: US 2024/0034907 A1
(43) Pub. Date: Feb. 1, 2024

(54) POLISHING COMPOSITION, POLISHING METHOD AND METHOD FOR PRODUCING SEMICONDUCTOR SUBSTRATE

(71) Applicant: FUJIMI INCORPORATED, Aichi (JP)

(72) Inventors: Sonosuke ISHIGURO, Aichi (JP); Yoshihiro Izawa, Aichi (JP); Masaki Tada, Aichi (JP)

(21) Appl. No.: 18/223,137

(22) Filed: Jul. 18, 2023

(30) Foreign Application Priority Data
Jul. 29, 2022 (JP) 2022-121532

(51) Int. Cl. C09G 1/02

(52) U.S. Cl. CPC C09G 1/02

(57) ABSTRACT

Provided is a polishing composition capable of polishing a layer containing an element in group 13 of the periodic table in a content of 40 mass % or more at a high polishing speed while reducing surface defects due to polishing. Provided is a polishing composition for use in polishing an object to be polished having a layer containing an element in group 13 of the periodic table in a content of 40 mass % or more, the polishing composition containing a cationically modified silica, a trialkylamine oxide, and an oxidizing agent, wherein the content of the trialkylamine oxide is 3 mass ppm or more and 40 mass ppm or less with respect to the total mass of the polishing composition, and the pH is less than 5.

### CROSS-REFERENCE TO RELATED APPLICATION

The entire disclosure of Japanese Patent Application No. 2022-121532 filed on Jul. 29, 2022, is incorporated herein by reference in its entirety.

### TECHNICAL FIELD

The present invention relates to a polishing composition, a polishing method, and a method for producing a semiconductor substrate.

### BACKGROUND ART

In recent years, a so-called chemical mechanical polishing (CMP) technique for polishing and flattening a semiconductor substrate in producing a device is used in accordance with multilayer wiring on a surface of a semiconductor substrate. CMP is a method for flattening a surface of an object to be polished (polishing object) such as a semiconductor substrate using a polishing composition (slurry) containing abrasive grains such as silica, alumina, or ceria, an anti-corrosion agent, a surfactant, or the like. The object to be polished (polishing object) is silicon, polysilicon, a silicon oxide film (silicon oxide), silicon nitride, a wiring or a plug which consists of metal, or the like.

For example, as a technique for polishing a polysilicon film provided on a silicon substrate including an isolation region, Japanese Patent Laid-Open No. 2007-103515 (corresponding to U.S. Patent Application No. 2007/0077764) discloses a polishing method including a step of performing preliminarily polishing using a preliminary polishing composition containing abrasive grains, an alkali, a water-soluble polymer and water, and a step of performing finish polishing using a finish polishing composition containing abrasive grains, an alkali, a water-soluble polymer and water.

### SUMMARY OF INVENTION

### Technical Problem

The recent use of a substrate having a layer containing an element in group 13 of the periodic table in a content of 40 mass % or more as a semiconductor substrate leads to a new requirement of polishing the substrate. Such requirement has almost never been examined.

Thus, an object of the present invention is to provide a polishing composition making it possible to polish a layer containing an element in group 13 of the periodic table in a content of 40 mass % or more at a high polishing speed while being capable of reducing the surface defects of the layer due to polishing.

### Solution to Problem

The inventors of the present invention have intensively studied to solve the above new problems. As a result, the inventors have discovered that the above problems can be solved by a polishing composition containing a cationically modified silica, a trialkylamine oxide, and an oxidizing agent, wherein the content of the trialkylamine oxide is 3 mass ppm or more and 40 mass ppm or less with respect to the total mass of the polishing composition, and the pH is less than 5, and thus have completed the present invention.

Specifically, the present invention is a polishing composition for use in polishing an object to be polished having a layer containing an element in group 13 of the periodic table in a content of 40 mass % or more, the polishing composition containing a cationically modified silica, a trialkylamine oxide, and an oxidizing agent, wherein the content of the trialkylamine oxide is 3 mass ppm or more and 40 mass ppm or less with respect to the total mass of the polishing composition, and the pH is less than 5.

### DESCRIPTION OF EMBODIMENTS

The present invention is a polishing composition for use in polishing an object to be polished having a layer containing an element in group 13 of the periodic table in a content of 40 mass % or more, the polishing composition containing a cationically modified silica, a trialkylamine oxide, and an oxidizing agent, wherein the content of the trialkylamine oxide is 3 mass ppm or more and 40 mass ppm or less with respect to the total mass of the polishing composition, and the pH is less than 5. The polishing composition according to an embodiment of the present invention having such a configuration makes it possible to polish a layer containing an element in group 13 of the periodic table in a content of 40 mass % or more at a high polishing speed while being capable of reducing surface defects due to the polishing.

Embodiments of the present invention will be described below, but the present invention is not limited to only the following embodiments.

Throughout the specification, singular expressions should be understood to include the concept of the plural expressions as well, unless otherwise specified. Therefore, singular articles (for example, “a”, “an”, “the” etc., in the case of English) should be understood to include the concept of the plural forms as well, unless otherwise specified. Further, it should be understood that the terms used herein have meanings commonly used in the art, unless otherwise specified. Therefore, unless defined otherwise, all technical and scientific terms used herein have the same meaning as commonly understood by a person skilled in the art to which the present invention belongs. In case of conflict, the present specification including definitions, will control.

In this specification, unless otherwise specified, operation and measurement of physical properties, etc., are performed under conditions of room temperature (20° C. or higher and 25° C. or lower)/relative humidity of 40% RH or more and 50% RH or less.

### Object to be Polished

The object to be polished according to the present invention has a layer containing an element in group 13 of the periodic table in a content of 40 mass % or more (hereinafter, also simply referred to as a group 13 element layer). Examples of an element in group 13 of the periodic table include boron (B), aluminum (Al), gallium (Ga) and indium (In). These group 13 elements may be contained singly or in combinations of two or more thereof.

The group 13 element layer may also contain other elements other than an element in group 13 of the periodic table. Examples of other elements include silicon (Si), hydrogen (H), nitrogen (N), oxygen (O), carbon (C), phosphorus (P) and germanium (Ge). These other elements may be contained singly or in combinations of two or more thereof.

The lower limit of an element in group 13 of the periodic table contained in the group 13 element layer is 40 mass % or more, preferably 45 mass % or more, and more preferably 50 mass % or more with respect to the total mass of the layer. Further, the upper limit of an element in group 13 of the periodic table contained in the group 13 element layer is preferably 100 mass % or less with respect to the total mass of the layer. Specifically, the amount of the element in group 13 of the periodic table contained in the group 13 element layer ranges from preferably 40 mass % to 100 mass %, more preferably 45 mass % to 100 mass %, and further preferably 50 mass % to 100 mass % with respect to the total mass of the layer.

The object to be polished according to the present invention may further contain other materials other than the group 13 element layer. Examples of other materials include silicon nitride, silicon carbonitride (SiCN), silicon oxide, polycrystalline silicon (polysilicon), non-crystalline silicon (amorphous silicon), polycrystalline silicon doped with an n-type impurity, non-crystalline silicon doped with an n-type impurity, titanium nitride, a simple substance of metal, and SiGe.

Examples of an object to be polished containing silicon oxide include a TEOS (Tetraethyl Orthosilicate)-type silicon oxide plane (hereinafter, may also be referred to as “TEOS” or “TEOS film”) that is formed using tetraethyl orthosilicate as a precursor, an HDP (High Density Plasma) film, an USG (Undoped Silicate Glass) film, a PSG (Phosphorus Silicate Glass) film, a BPSG (Boron-Phospho Silicate Glass) film, and an RTO (Rapid Thermal Oxidation) film.

Examples of a simple substance of metal include tungsten, copper, cobalt, hafnium, nickel, gold, silver, platinum, palladium, rhodium, ruthenium, iridium, and osmium.

Moreover, the object to be polished according to the present invention may further contain a material having a content of an element in group 13 of the periodic table of more than 0 mass % and less than 40 mass %. Examples of such a material include polycrystalline silicon doped with a p-type impurity and non-crystalline silicon doped with a p-type impurity.

### Cationically Modified Silica

The polishing composition according to the present invention contains cationically modified silica (silica having cationic groups) as abrasive grains. One cationically modified silica may be used, or two or more thereof may be used in combination. Further, commercial products or synthetic products of cationically modified silica may also be used.

As the cationically modified silica, cationically modified colloidal silica (colloidal silica having cationic group) is preferable.

Examples of a method for producing colloidal silica include a soda silicate method and a sol-gel method, and colloidal silica produced by any of these methods is suitably used as abrasive grains according to the present invention. However, from the viewpoint of reducing metal impurities, colloidal silica produced by a sol-gel method is preferable, since such colloidal silica produced by a sol-gel method has a low content of metal impurities diffusible in a semiconductor and corrosive ions such as chloride ions. Production of colloidal silica by such a sol-gel method can be performed by a conventionally known technique. Specifically, hydrolysis and condensation reaction are performed using a hydrolysable silicon compound (for example, alkoxysilane or a derivative thereof) as a raw material, so that colloidal silica can be obtained.

Here, the term “cationically modified” means a state in which a cationic group (for example, an amino group or a quaternary ammonium group) is bound to a surface of silica (preferably colloidal silica). Further, according to a preferred embodiment of the present invention, cationically modified silica particles are amino group-modified silica particles, and more preferably amino group-modified colloidal silica particles. According to such an embodiment, the above effect can be even more improved.

Silica (colloidal silica) is cationically modified by adding a silane coupling agent having a cationic group (for example, an amino group or a quaternary ammonium group) to silica (colloidal silica) for reaction at a predetermined temperature for a predetermined time period. In a preferred embodiment of the present invention, a cationically modified silica is prepared by fixing a silane coupling agent having an amino group or a silane coupling agent having a quaternary ammonium group onto the surface of silica (more preferably colloidal silica).

Examples of a silane coupling agent to be used in such a case include those described in Japanese Patent Laid-Open No. 2005-162533. Specific examples thereof include silane coupling agents such as N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltriethoxysilane((3-aminopropyl)triethoxysilane), γ-aminopropyltrimethoxysilane, γ-triethoxysilyl-N-(α,γ-dimethyl-butylidene)propylamine, N-phenyl-γ-aminopropyltrimethoxysilane, a hydrochloride of N-(vinylbenzyl)-β-aminoethyl-γ-aminopropyltriethoxysilane, octadecyldimethyl-(γ-trimethoxysilylpropyl)-ammonium chloride, and N-trimethoxysilylpropyl-N,N,N-trimethylammonium chloride. Of these, because of good reactivity with colloidal silica, N-(β-aminoethyl)-γ-aminopropyltrimethoxysilane, N-(β-aminoethyl)-γ-aminopropyltriethoxysilane, γ-aminopropyltriethoxysilane, and γ-aminopropyltrimethoxysilane are preferably used. Note that in the present invention, one silane coupling agent may be used, or two or more thereof may be used in combination.

In addition, a silane coupling agent can be directly added to or diluted with a hydrophilic organic solvent or pure water and then added to silica (colloidal silica). Through dilution with a hydrophilic organic solvent or pure water, generation of aggregates can be suppressed. When a silane coupling agent is diluted with a hydrophilic organic solvent or pure water, the silane coupling agent may be diluted with a hydrophilic organic solvent or pure water in such a manner that the concentration of the silane coupling agent is about preferably 0.01 g or more and 1 g or less, and more preferably 0.1 g or more and 0.7 g or less in 1 L of the hydrophilic organic solvent or pure water. Examples of the hydrophilic organic solvent can include, but are not particularly limited to, lower alcohols such as methanol, ethanol, isopropanol, and butanol.

Further, through regulation of the amount of a silane coupling agent added, the amount of a cationic group to be introduced onto the surface of silica (colloidal silica) can be regulated. The amount of a silane coupling agent to be used is not particularly limited and is about preferably 0.1 mM (mmol/L) or more and 5 mM or less, and more preferably 0.5 mM or more and 3 mM or less with respect to the amount of a reaction solution.

Temperatures at which silica (colloidal silica) is cationically modified with a silane coupling agent are not particularly limited and may range from room temperature (e.g., 25° C.) to about the boiling point of a dispersing medium in which silica (colloidal silica) is dispersed. Specifically, the temperature is about 0° C. or higher and 100° C. or lower, and preferably room temperature (e.g., 25° C.) or higher and 90° C. or lower.

The shape of cationically modified silica is not particularly limited and may be globular (hereinafter, also referred to as spherical), or non-globular. Specific examples of a non-globular shape include various shapes, but are not particularly limited to, polygonal columnar shapes such as a triangle pole and a square pole, cylindrical shapes, a straw bag shape in which the center part of the cylinder is swollen more than the end parts, a donut shape in which the center part of the disk is hollow, a plate shape, a so-called cocoon shape having a constriction at the center part, a so-called associated type spherical shape in which a plurality of particles are integrated, a so-called kompeito shape having a plurality of protrusions on the surface; and a rugby ball shape.

The average primary particle size of the cationically modified silica is preferably 1 nm or more, more preferably 3 nm or more, and further preferably 5 nm or more. Further, the average primary particle size of the cationically modified silica is preferably 100 nm or less, more preferably 50 nm or less, and further preferably 30 nm or less. With the average primary particle size of the cationically modified silica, which is within the above ranges, the polishing speed for the group 13 element layer is more improved.

Specifically, the average primary particle size of the cationically modified silica is preferably 1 nm or more and 100 nm or less, more preferably 3 nm or more and 50 nm or less, and further preferably 5 nm or more and 30 nm or less. Note that the average primary particle size of the cationically modified silica can be calculated on the basis of the specific surface area (SA) of cationically modified silica, as calculated by a BET method, and the density of the cationically modified silica, for example.

Further, the average secondary particle size of the cationically modified silica is preferably 15 nm or more, more preferably 20 nm or more, further preferably 25 nm or more, and particularly preferably 30 nm or more. As the average secondary particle size of the cationically modified silica increases, resistance during polishing decreases to enable stable polishing. Further, the average secondary particle size of the cationically modified silica is preferably 200 nm or less, more preferably 150 nm or less, further preferably 100 nm or less, and particularly preferably 70 nm or less. As the average secondary particle size of the cationically modified silica decreases, the surface area per unit mass of the cationically modified silica increases, the frequency of contact with an object to be polished is improved, and the polishing speed is more improved. Specifically, the average secondary particle size of the cationically modified silica is preferably 15 nm or more and 200 nm or less, more preferably 20 nm or more and 150 nm or less, further preferably 25 nm or more and 100 nm or less, and particularly preferably 30 nm or more and 70 nm or less. Note that as the average secondary particle size of the cationically modified silica, a value measured by a method described in Examples is employed.

The ratio of the average secondary particle size to the average primary particle size of the cationically modified silica (average secondary particle size/average primary particle size, hereinafter, also referred to as “average degree of association”) is preferably more than 1.0, more preferably 1.1 or more, further preferably 1.2 or more, and particularly preferably 1.5 or more. Further, the average degree of association of the cationically modified silica is preferably 4 or less, more preferably 3.5 or less, further preferably 3 or less, and particularly preferably 2.5 or less. With the average degree of association of the cationically modified silica, which is within the above ranges, the polishing speed for the group 13 element layer is more improved. Specifically, the average degree of association of the cationically modified silica is preferably more than 1.0 and 4 or less, more preferably 1.1 or more and 3.5 or less, further preferably 1.2 or more and 3 or less, and particularly preferably 1.5 or more and 2.5 or less.

Note that the average degree of association of the cationically modified silica is obtained by dividing the value of the average secondary particle size of the cationically modified silica by the value of the average primary particle size of the cationically modified silica.

The upper limit of the aspect ratio of the cationically modified silica in a polishing composition is not particularly limited, but is preferably less than 2.0, more preferably 1.8 or less, and further preferably 1.5 or less. With the upper limit within such ranges, defects on a surface of an object to be polished can be even more reduced. Note that the aspect ratio is an average value of values, each of which is obtained by dividing the length of the long side of a rectangle by the length of a short side of the rectangle, where the rectangle is the minimum rectangle circumscribing each image of cationically modified silica particles obtained by the use of a scanning electron microscope. The aspect ratio can be found using a general image analysis software. The lower limit of the aspect ratio of the cationically modified silica in a polishing composition is not particularly limited, but is preferably 1.0 or more.

In the particle size distribution determined by subjecting the cationically modified silica to a laser diffraction/scattering method, the lower limit of D90/D50 that is the ratio of particle diameter (D90) when the weight of accumulated particles from the particulate side reaches 90% of the total weight of particles to particle diameter (D50) when the same reaches 50% of the total weight of particles is not particularly limited, but is preferably 1.1 or more, more preferably 1.2 or more, and further preferably 1.3 or more. Further, in the particle size distribution determined by subjecting the cationically modified silica in a polishing composition to a laser diffraction/scattering method, the upper limit of D90/D50 that is the ratio of particle diameter (D90) when the weight of accumulated particles from the particulate side reaches 90% of the total weight of particles to particle diameter (D50) when the same reaches 50% of the total weight of particles is not particularly limited, but is preferably 2.0 or less, more preferably 1.7 or less, and further preferably 1.5 or less. With the limits within such ranges, defects on a surface of an object to be polished can be more reduced.

The sizes of cationically modified silica (e.g., average primary particle size, average secondary particle size, aspect ratio, and D90/D50) can be appropriately controlled by selection and the like of a method for producing a cationically modified silica.

The lower limit of the zeta potential of the cationically modified silica in the polishing composition is preferably 4 mV or more, more preferably 4.5 mV or more, and further preferably 5 mV or more. Further, the upper limit of the zeta potential of the cationically modified silica in the polishing composition is preferably 70 mV or less, more preferably 65 mV or less, and further preferably 60 mV or less. Specifically, the zeta potential of the cationically modified silica in the polishing composition is preferably 4 mV or more and 70 mV or less, more preferably 4.5 mV or more and 65 mV or less, and further preferably 5 mV or more and 60 mV or less.

With the cationically modified silica having the above-described zeta potential, the group 13 element layer can be polished at an even higher polishing speed.

In this specification, as the zeta potential of the cationically modified silica, a value measured by a method described in Examples is employed. The zeta potential of the cationically modified silica can be adjusted using the amount of cationic groups contained in the cationically modified silica and the pH or the like of the polishing composition.

The content (concentration) of the cationically modified silica in the polishing composition is not particularly limited, but is preferably 0.1 mass % or more, more preferably 0.2 mass % or more, further preferably 0.5 mass % or more, and particularly preferably more than 0.5 mass % with respect to the total mass of the polishing composition. Further, the upper limit of the content of the cationically modified silica in the polishing composition is preferably 10 mass % or less, more preferably 8 mass % or less, and further preferably 6 mass % or less with respect to the total mass of the polishing composition. Specifically, the content of the cationically modified silica is preferably 0.1 mass % or more and 10 mass % or less, more preferably 0.2 mass % or more and 8 mass % or less, further preferably 0.5 mass % or more and 6 mass % or less, and particularly preferably more than 0.5 mass % and 6 mass % or less with respect to the total mass of the polishing composition. With the cationically modified silica content within such ranges, the group 13 element layer can be polished at an even higher polishing speed. Note that in this specification, a description concerning the content etc., of a substance(s) refers to the total amount of the substances when the two or more substances are contained. For example, when the polishing composition contains two or more cationically modified silicas, the content of the cationically modified silicas refers to the total amount of these cationically modified silicas.

The polishing composition according to the present embodiment may further contain other abrasive grains other than the cationically modified silica to such an extent that the effects of the present invention are not impaired. Such other abrasive grains may be any of inorganic particles, organic particles, and organic and inorganic composite particles. Specific examples of the inorganic particles include particles composed of metal oxide such as untreated silica, alumina, ceria, or titania, silicon nitride particles, silicon carbide particles, and boron nitride particles. Specific examples of the organic particles include methyl polymethacrylate (PMMA) particles. Such other abrasive grains may be used singly or in a mixture of two or more thereof. Further, commercial products or synthetic products of such other abrasive grains may also be used.

### Trialkylamine Oxide

The polishing composition according to the present invention contains a trialkylamine oxide. In the polishing composition according to the present invention, the trialkylamine oxide has an action of accelerating the polishing of a group 13 element layer and further an action of reducing defects due to polishing on a surface of an object to be polished. Details of the reason why the trialkylamine oxide can accelerate the polishing of an object to be polished and can further reduce defects on a surface of the object to be polished are unknown, but we consider the reason as follows. A trialkylamine oxide has a positive charge in an acidic region, however, when the trialkylamine oxide is adhered to a surface of an object to be polished having a group 13 element layer, electrostatic attraction functions between the trialkylamine oxide and a group 13 element. This increases the bond distance of the group 13 element, making the surface of the object to be polished brittle. In this manner, the trialkylamine oxide is considered to be able to accelerate the polishing of the object to be polished. Moreover, when such a trialkylamine oxide having a positive charge is adhered to a surface of an object to be polished, the charge on the surface of the object to be polished is partially changed to positive. This is considered to make it difficult for abrasive grains to be adsorbed to the surface of the object to be polished, so that defects on the surface of the object to be polished can be reduced.

Note that the above mechanism is a result of speculation, and the present invention is not limited to the above mechanism.

One trialkylamine oxide may be used, or two or more thereof may be used in combination. Further, commercial products or synthetic products of a trialkylamine oxide may also be used.

The number of carbon atoms of an alkyl group in the trialkylamine oxide according to the present embodiment is not particularly limited, and is preferably 1 or more and 20 or less. Further, the alkyl group may be any of a linear, a branched, and a cyclic alkyl group.

Specific examples of an alkyl group include:
a linear alkyl group such as a methyl group, an ethyl group, a n-propyl group, a n-butyl group, a n-pentyl group, a n-hexyl group, a n-heptyl group, a n-octyl group, a n-nonyl group, a n-decyl group, a n-undecyl group, a lauryl group (n-dodecyl group), a n-tridecyl group, a myristyl group (n-tetradecyl group), a n-pentadecyl group, a n-hexadecyl group, a n-heptadecyl group, a n-octadecyl group, a n-nonadecyl group, and a n-icosyl group;
a branched alkyl group such as an isopropyl group, an isobutyl group, a sec-butyl group, a tert-butyl group, a 2-ethylbutyl group, a 3,3-dimethylbutyl group, a 1,1,3,3-tetramethylbutyl group, a 1-methylbutyl group, a 1-ethylpropyl group, a 3-methylbutyl group, a neopentyl group, a 1,1-dimethylpropyl group, 2-methylpentyl group, a 3-ethylpentyl group, a 1,3-dimethylbutyl group, 2-propylpentyl group, 1-ethyl-1,2-dimethylpropyl group, a 1-methylpentyl group, a 4-methylpentyl group, a 4-methylhexyl group, a 5-methylhexyl group, a 2-ethylhexyl group, a 1-methylhexyl group, a 1-ethylpentyl group, a 1-propylbutyl group, a 3-ethylheptyl group, a 2,2-dimethylheptyl group, a 1-methylheptyl group, a 1-ethylhexyl group, a 1-propylpentyl group, a 1-methyloctyl group, a 1-ethylheptyl group, a 1-propylhexyl group, a 1-butylpentyl group, a 1-methylnonyl group, a 1-ethyloctyl group, a 1-propylheptyl group, and a 1-butylhexyl group; and
a cyclic cycloalkyl group such as a cyclopropyl group, a 1-methylcyclopropyl group, a cyclobutyl group, a cyclopentyl group, a cyclohexyl group, a cycloheptyl group, a 1-methylcyclohexyl group, a 2-methylcyclohexyl group, a 3-methylcyclohexyl group, a 4-methylcyclohexyl group, a 1,2-dimethylcyclohexyl group, a 1,3-dimethylcyclohexyl group, a 1,4-dimethylcyclohexyl group, a 2,3-dimethylcyclohexyl group, a 2,4-dimethylcyclohexyl group, a 2,5-dimethylcyclohexyl group, a 2,6-dimethylcyclohexyl group, a 3,4-dimethylcyclohexyl group, a 3,5-dimethylcyclohexyl group, a 2,2-dimethylcyclohexyl group, a 3,3-dimethylcyclohexyl group, a 4,4-dimethylcyclohexyl group, a cyclooctyl group, a 2,4,6-trimethylcyclohexyl group, a 2,2,6,6-tetramethylcyclohexyl group, a 3,3,5,5-tetramethylcyclohexyl group, a 4-pentylcyclohexyl group, a 4-octylcyclohexyl group, and a 4-decylcyclohexyl group. The three types of the alkyl group of the trialkylamine oxide may be the same or different from each other, or may be composed of the same two alkyl groups and one different alkyl group.

More specific examples of the trialkylamine oxide include triethylamine oxide, tri(n-propyl)amine oxide, triisopropylamine oxide, tricyclopropylamine oxide, tri(n-butyl)amine oxide, tri(sec-butyl)amine oxide, triisobutylamine oxide, tri(tert-butyl)amine oxide, tricyclobutylamine oxide, tri(n-pentyl)amine oxide, tri(1-methylbutyl)amine oxide, tri(2-methylbutyl)amine oxide, triisopentylamine oxide, tri(tert-pentyl)amine oxide, tri(1,2-dimethylpropyl)amine oxide, trineopentylamine oxide, tricyclopentylamine oxide, tri(n-hexyl)amine oxide, tri(1-methylpentyl)amine oxide, tri(2-methylpentyl)amine oxide, tri(3-methylpentyl)amine oxide, triisohexylamine oxide, tri(1,1-dimethylbutyl)amine oxide, tri(1,2-dimethylbutyl)amine oxide, tri(1,3-dimethylbutyl)amine oxide, tri(2,2-dimethylbutyl)amine oxide, tri(3,3-dimethylbutyl)amine oxide, tricyclohexylamine oxide, tri(n-heptyl)amine oxide, tri(1-methylhexyl)amine oxide, tricycloheptylamine oxide, tri(n-octyl)amine oxide, tri(1-methylheptyl)amine oxide, triisooctylamine oxide, tricyclooctylamine oxide, tri(n-nonyl)amine oxide, tri(1-methyloctyl)amine oxide, tricyclononylamine oxide, tri(n-decyl)amine oxide, tri(1-methylnonyl)amine oxide, tricyclodecylamine oxide, tri(n-undecyl)amine oxide, tri(1-methyldecyl)amine oxide, tricycloundecylamine oxide, tri(n-dodecyl)amine oxide, tricyclododecylamine oxide, tri(n-tridecyl)amine oxide, tricyclotridecylamine oxide, tri(n-tetradecyl)amine oxide, tricyclotetradecylamine oxide, tri(n-pentadecyl)amine oxide, tri(n-hexadecyl)amine oxide, tri(n-heptadecyl) amine oxide, tri(n-octadecyl)amine oxide, tri(n-nonadecyl)amine oxide, tri(n-icosyl)amine oxide; n-hexyldimethylamine oxide, n-heptyldimethylamine oxide, n-octyldimethylamine oxide, n-nonyldimethylamine oxide, n-decyldimethylamine oxide, n-undecyldimethylamine oxide, isododecyldimethylamine oxide, lauryldimethylamine oxide(n-dodecyldimethylamine oxide), myristyldimethylamine oxide(n-tetradecyldimethylamine oxide), isotridecyldimethylamine oxide, n-pentadecyldimethylamine oxide, n-hexadecyldimethylamine oxide, n-heptadecyldimethylamine oxide, and n-octadecyldimethylamine oxide(stearyldimethylamine oxide).

In particular, at least one alkyl group of the trialkylamine oxide has preferably 8 or more and 20 or less, more preferably 10 or more and 18 or less, and further preferably 11 or more and 13 or less carbon atoms. The trialkylamine oxide having a long-chain alkyl group having carbon atoms within the above ranges can achieve the effects of the present invention more efficiently.

The type of such a long-chain alkyl group is not particularly limited, but such a long-chain alkyl group has preferably at least one selected from the group consisting of a n-octyl group, a n-nonyl group, a n-decyl group, a n-undecyl group, a lauryl group (n-dodecyl group), a n-tridecyl group, a myristyl group (n-tetradecyl group), a n-pentadecyl group, a n-hexadecyl group, a n-heptadecyl group, a n-octadecyl group, a n-nonadecyl group, and a n-icosyl group, and more preferably at least one selected from the group consisting of a n-decyl group, a lauryl group, a myristyl group, and a n-octadecyl group. The trialkylamine oxide has the above alkyl group, so that the effects of the present invention can be obtained more efficiently.

The trialkylamine oxide according to the present embodiment is preferably at least one selected from the group consisting of n-decyldimethylamine oxide, lauryldimethylamine oxide, myristyldimethylamine oxide, and n-octadecyldimethylamine oxide. Furthermore, the trialkylamine oxide is more preferably a lauryldimethylamine oxide. The trialkylamine oxide is the above compound, so that polishing can be accelerated more sufficiently and surface defects due to polishing can be reduced more sufficiently.

The content of the trialkylamine oxide in the polishing composition according to the present invention is 3 mass ppm or more and 40 mass ppm or less with respect to the total mass of the polishing composition. When the content of the trialkylamine oxide is less than 3 mass ppm, the rate of adsorption of the trialkylamine oxide to a surface of an object to be polished is low. Accordingly, the cationically modified silica is in excessive contact with the object to be polished, and thus surface defects due to polishing cannot be sufficiently reduced. On the other hand, when the content of trialkyl amine oxide is more than 40 mass ppm, the rate of adsorption of the trialkylamine oxide to a surface of an object to be polished is high. Accordingly, the approach of the cationically modified silica toward the object to be polished is excessively inhibited during polishing, so that the polishing speed is decreased.

The content of the trialkylamine oxide in the present embodiment is preferably 4 mass ppm or more and 35 mass ppm or less, and more preferably 5 mass ppm or more and 30 mass ppm or less with respect to the total mass of the polishing composition. The trialkylamine oxide is contained in the polishing composition in an amount within the above ranges, so that the effects of the present invention can be obtained more efficiently. When the polishing composition contains two or more trialkylamine oxides, the content of the trialkylamine oxides refers to the total amount of these oxides.

### Oxidizing Agent

The polishing composition according to the present invention contains an oxidizing agent. The oxidizing agent accelerates the polishing of an object to be polished containing a group 13 element layer.

Examples of the oxidizing agent include hydrogen peroxide, sodium peroxide, barium peroxide, ozone water, silver (II) salt, iron (III) salt, permanganic acid, chromic acid, dichromic acid, peroxydisulfuric acid, peroxophosphoric acid, peroxosulfuric acid, peroxoboric acid, performic acid, peracetic acid, perbenzoic acid, perphthalic acid, hypochlorous acid, hypobromous acid, hypoiodous acid, chloric acid, chlorous acid, perchloric acid, bromic acid, iodic acid, periodic acid, persulfuric acid, and dichloroisocyanuric acid. The oxidizing agent may be used singly or in a mixture of two or more thereof.

Further, commercial products of the oxidizing agent may be used and synthetic products thereof may also be used. Of these, from the viewpoint of further improving the effects of the present invention, the oxidizing agent is preferably hydrogen peroxide.

The content (concentration) of the oxidizing agent in the polishing composition is not particularly limited, but is preferably 1 mass % or more and 5 mass % or less, more preferably 2 mass % or more and 4 mass % or less, and further preferably 2.5 mass % or more and 3.5 mass % or less with respect to the total mass of the polishing composition. With the oxidizing agent content within such ranges, a group 13 element layer can be polished at a sufficiently higher polishing speed, and surface defects due to polishing can be sufficiently reduced. When the polishing composition contains two or more oxidizing agents, the content of the oxidizing agents refers to the total amount of these oxidizing agents.

### pH

The pH of the polishing composition according to the present invention is less than 5. With the pH of 5 or higher, the zeta potential of the cationically modified silica decreases to hinder the electrostatic attraction between the polishing composition and an object to be polished, and thus the polishing speed decreases and the number of defects increases.

The pH of the polishing composition according to the present embodiment is preferably 1 or more and less than 5, more preferably 2 or more and less than 4, and further preferably 2 or more and 3 or less. The pH of the polishing composition within such ranges makes it possible to polish a group 13 element layer at an even higher polishing speed.

Note that the pH of the polishing composition can be obtained by performing 3-point calibration using a pH meter (for example, a glass electrode hydrogen ion concentration indicator (Model No.: F-23) manufactured by HORIBA, Ltd.) and standard buffers (phthalate pH buffer pH: 4.01 (25° C.), neutral phosphate pH buffer pH: 6.86 (25° C.), carbonate pH buffer pH: 10.01 (25° C.)), placing the glass electrode in the polishing composition, and then measuring the value stabilized after 2 or more minutes.

The polishing composition according to the present invention contains a cationically modified silica, a trialkylamine oxide, and an oxidizing agent as essential components. However, when it is difficult to obtain a desired pH with these components alone, a pH adjusting agent may be added to adjust the pH to such an extent that the effects of the present invention are not impaired.

The pH adjusting agent is not particularly limited, as long as it is a compound capable of adjusting pH and known compounds can be used. The pH adjusting agent is not particularly limited as long as it is capable of adjusting pH, and examples thereof include an acid and an alkali.

As the acid, either an inorganic acid or an organic acid may be used. Examples of the inorganic acid include, but are not particularly limited to, sulfuric acid, nitric acid, boric acid, carbonic acid, hypophosphorous acid, phosphorous acid, and phosphoric acid. Examples of the organic acid include, but are not particularly limited to, carboxylic acid such as 1-hydroxyethylidene-1,1-diphosphonic acid (HEDP), formic acid, acetic acid, propionic acid, butyric acid, valeric acid, 2-methylbutanoic acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, as well as methanesulfonic acid, ethanesulfonic acid, and isethionic acid. Of these, an organic acid is preferable and 1-hydroxyethylidene-1,1-diphosphonic acid (HEDP), malic acid, citric acid, and maleic acid are more preferable. Note that when an inorganic acid is used, nitric acid, sulfuric acid, and phosphoric acid are preferable.

Examples of the alkali include, but are not particularly limited to, a hydroxide of alkali metal such as potassium hydroxide, ammonia, a quaternary ammonium salt such as tetramethylammonium and tetraethylammonium, and an amine such as ethylenediamine and piperazine. Of these, potassium hydroxide and ammonia are preferable.

Note that one pH adjusting agent can be used, or two or more thereof may be used in combination.

The amount of the pH adjusting agent added is not particularly limited and may be adequately adjusted so that the polishing composition has a desired pH.

### Antifungal Agent

The polishing composition according to the present embodiment may further contain an antifungal agent to such an extent that the effects of the present invention are not impaired. As the antifungal agent, a known antifungal agent that can be used for the polishing composition can be used. Examples thereof include isothiazoline-based antiseptic agents such as 1,2-benzoisothiazol-3(2H)-one, 2-methyl-4-isothiazolin-3-one and 5-chloro-2-methyl-4-isothiazolin-3-one, parahydroxybenzoic acid esters, and phenoxyethanol. These antiseptic agents and antifungal agents may be used singly or in a mixture of two or more thereof.

### Dispersing Medium

The polishing composition according to the present embodiment may contain a dispersing medium for dispersing each component. Examples of the dispersing medium can include water, alcohols such as methanol, ethanol, and ethylene glycol, ketones such as acetone, and mixtures thereof. Of these, water is preferable as a dispersing medium. Specifically, examples of the dispersing medium for the polishing composition according to the present embodiment include water, and further preferably the dispersing medium is substantially composed of water. Note that the above “substantially” is intended to mean that a dispersing medium other than water can be contained as long as the effects of the present invention can be achieved. More specifically, the dispersing medium is composed of preferably 90 mass % or more and 100 mass % or less of water and 0 mass % or more and 10 mass % or less of a dispersing medium other than water, and more preferably 99 mass % or more and 100 mass % or less of water and 0 mass % or more and 1 mass % or less of a dispersing medium other than water. Most preferably, the dispersing medium is water.

Water containing impurities in an amount as low as possible is preferable as the dispersing medium from the viewpoint of not inhibiting the action of components contained in the polishing composition. Specifically, pure water or ultra-pure water, which is obtained by removing foreign matter through a filter after removal of impurity ions using an ion exchange resin, or distilled water is more preferable.

### Other Components

The polishing composition according to the present embodiment may further contain a known additive such as a complexing agent, and an antiseptic agent, which can be used for the polishing composition, to such an extent that the effects of the present invention are not impaired.

### Method for Producing Polishing Composition

A method for producing the polishing composition according to the present invention is not particularly limited. For example, the polishing composition can be obtained by mixing and stirring a cationically modified silica, a trialkylamine oxide, an oxidizing agent, and other additives as necessary in a dispersing medium (e.g., water). Each component is as described in detail above.

Temperature at which each component is mixed is not particularly limited, and the temperature is preferably 10° C. or higher and 40° C. or lower, and the mixture may also be heated in order to increase the rate of dissolution. Further the time for mixing is not particularly limited, as long as the mixture can be mixed uniformly.

### Polishing Method and Method for Producing Semiconductor Substrate

As described above, the polishing composition according to the present embodiment is suitably used for polishing an object to be polished having a group 13 element layer. Hence, the present invention provides a polishing method that involves a step of polishing an object to be polished having a layer containing an element in group 13 of the periodic table in a content of 40 mass % or more using the polishing composition according to the present embodiment. Further, the present invention provides a method for producing a semiconductor substrate, which involves polishing a semiconductor substrate having a layer containing an element in group 13 of the periodic table in a content of 40 mass % or more by the above polishing method.

As a polishing apparatus, it is possible to use a general polishing apparatus including a holder for holding a substrate or the like having an object to be polished, a motor having a changeable rotational speed or the like fitted thereto, and a platen to which a polishing pad (polishing cloth) can be attached.

As the polishing pad, general nonwoven fabric, polyurethane, a porous fluororesin, or the like can be used without any particular limitation. The polishing pad is preferably grooved such that a polishing liquid can be stored therein.

Regarding polishing conditions, for example, the rotational speed of a platen is preferably 10 rpm (0.17 s⁻¹) or more and 500 rpm (8.33 s⁻¹) or less. The pressure (polishing pressure) applied to a substrate having an object to be polished is preferably 0.5 psi (3.4 kPa) or more and 10 psi (68.9 kPa). A method for feeding the polishing composition to a polishing pad is also not particularly limited. For example, a method for continuously feeding the polishing composition using a pump or the like is employed. The feed rate is not limited, but a surface of the polishing pad is preferably covered all the time with the polishing composition according to the present invention.

After completion of polishing, the substrate is cleaned in running water, water droplets adhered onto the substrate are removed using a spin dryer or the like for drying, and thus the substrate having a group 13 element layer is obtained.

The polishing composition according to the present invention may be of a single-fluid type or multi-fluid type including double-fluid type. Further, the polishing composition according to the present invention may be prepared by, for example, diluting 10 or more times an undiluted solution of the polishing composition using a diluent such as water.

The embodiments of the present invention are described in detail above, but are given for explanatory and illustrative purposes only, and are not limited. The scope of the present invention should be obviously construed on the basis of the attached claims.

The present invention encompasses following aspects and embodiments:
[1] A polishing composition for use in polishing an object to be polished having a layer containing an element in group 13 of the periodic table in a content of 40 mass % or more, the polishing composition comprising:
   a cationically modified silica, a trialkylamine oxide, and an oxidizing agent,
   wherein the content of the trialkylamine oxide is 3 mass ppm or more and 40 mass ppm or less with respect to the total mass of the polishing composition, and the pH is less than 5.
[2] The polishing composition according to [1] above, wherein the pH is 2 or more and less than 4.
[3] The polishing composition according to [1] or [2] above, wherein the trialkylamine oxide has at least one alkyl group having 8 or more and 20 or less carbon atoms.
[4] The polishing composition according to any one of [1] to [3] above, wherein the trialkylamine oxide has at least one selected from the group consisting of a n-decyl group, a lauryl group, a myristyl group, and a n-octadecyl group.
[5] The polishing composition according to any one of [1] to [4] above, wherein the trialkylamine oxide is at least one selected from the group consisting of a n-decyldimethylamine oxide, a lauryldimethylamine oxide, a myristyldimethylamine oxide, and a n-octadecyldimethylamine oxide.
[6] The polishing composition according to any one of [1] to [5] above, wherein the content of the oxidizing agent is 1 mass % or more and 5 mass % or less with respect to the total mass of the polishing composition.
[7] The polishing composition according to any one of [1] to [6] above, wherein the oxidizing agent is hydrogen peroxide.
[8] The polishing composition according to any one of [1] to [7] above, further comprising an antifungal agent.
[9] A polishing method, comprising a step of polishing an object to be polished having a layer containing an element in group 13 of the periodic table in a content of 40 mass % or more using the polishing composition according to any one of [1] to [8] above.
[10] A method for producing a semiconductor substrate, comprising polishing a semiconductor substrate having a layer containing an element in group 13 of the periodic table in a content of 40 mass % or more by the polishing method according to [9] above.

### EXAMPLES

The present invention will be described in more detail using the following Examples and Comparative Examples, but the technical scope of the present invention is not limited to only the following Examples. Note that unless otherwise specified, “%” and “part(s)” refer to “mass %” and “parts by mass”, respectively.

### Average Primary Particle Size of Abrasive Grains

The average primary particle size of abrasive grains was calculated from the specific surface area of silica particles measured by the BET method using “Flow Sorb II 2300” manufactured by Micromeritics and the density of abrasive grains.

### Average Secondary Particle Size of Abrasive Grains

The average secondary particle size of abrasive grains was measured as volume-mean particle size (arithmetic mean diameter of standard volume; Mv) using a dynamic light scattering particle sizeparticle size distribution apparatus UPA-UTI151 (manufactured by Nikkiso Co., Ltd.).

### Average Degree of Association of Abrasive Grains

The average degree of association of abrasive grains was calculated by dividing the value of the average secondary particle size of the abrasive grains by the value of the average primary particle size of the abrasive grains.

### Zeta Potential of Abrasive Grains

The zeta potential of abrasive grains in the polishing composition was calculated by subjecting a polishing composition to measurement by a laser doppler method (electrophoretic light scattering method) using Zetasizer Nano manufactured by Malvern Panalytical Ltd., under conditions of the measurement temperature of 25° C., and then analyzing the thus obtained data with Smoluchowski's formula.

### pH of Polishing Composition

Regarding the pH of each polishing composition, 3-point calibration was performed using a glass electrode hydrogen ion concentration indicator (manufactured by HORIBA, Ltd., Model No.: F-23) and standard buffers (phthalate pH buffer pH: 4.01 (25° C.), neutral phosphate pH buffer pH: 6.86 (25° C.), carbonate pH buffer pH: 10.01 (25° C.)), and then the glass electrode was placed in the polishing composition, thereby finding the value stabilized after 2 or more minutes as the pH value.

[Preparation of Polishing Composition]

(Example 1)

In the manner same as the method described in Example 1 of Japanese Patent Laid-Open No. 2005-162533, γ-aminopropyltriethoxysilane (APTES) was used as a silane coupling agent at the concentration of 2 mmol (2 mM) for 1 L of silica sol (methanol solution, silica concentration=20 mass %), thereby preparing cocoon-shaped cationically modified colloidal silica having an average primary particle size: 25.0 nm, an average secondary particle size: 50.0 nm, an average degree of association: 2.0.

The above-obtained cationically modified colloidal silica as abrasive grains was added to pure water as a dispersing medium at room temperature (25° C.) so that the final concentration thereof was 4 mass %, and then BIT (1,2-benzoisothiazol-3(2H)-one, manufactured by San-Ai Oil Co., Ltd. (currently, SAN-AI OBBLI CO., LTD.)) was added as an antifungal agent, so that the final concentration thereof was 0.3 g/kg, thereby obtaining a mixed solution.

Subsequently, to the mixed solution, a lauryldimethylamine oxide (manufactured by NOF Corporation) that was a trialkylamine oxide was added as a water-soluble additive so that the final concentration was 5 mass ppm, and then a 31 mass % of hydrogen peroxide aqueous solution (manufactured by SANTOKU CHEMICAL INDUSTRIES Co., Ltd.) was added as an oxidizing agent, so that the final concentration of the hydrogen peroxide was 3.1 mass %. Subsequently, nitric acid was used as a pH adjusting agent to adjust the pH of the mixed solution to be 2.5, and then the solution was stirred and mixed at room temperature (25° C.) for 30 minutes, thereby preparing a polishing composition.

Further, the zeta potential of the cationically modified colloidal silica in the obtained polishing composition was measured according to the above method and the result was +25 mV. Moreover, the particle size of the cationically modified colloidal silica in the polishing composition was the same as the particle size of the cationically modified colloidal silica used.

(Examples 2 to 12, Comparative Examples 1 to 13)

Except for changing the type and the concentration (mass ppm) of each water-soluble additive, the content (mass %) of each oxidizing agent, and the pH as described in Table 1-1 and Table 1-2 below, polishing compositions were prepared in the same manner as in Example 1. The composition of each polishing composition is as shown in Table 1-1 and Table 1-2 below.

Note that water-soluble additives are as specifically described below.
Lauryldimethylamine oxide: manufactured by NOF Corporation
n-Decyldimethylamine oxide: manufactured by Lion Corporation
Myristyldimethylamine oxide: manufactured by FUJIFILM Wako Pure Chemical Corporation
n-Octadecyldimethylamine oxide: manufactured by ZHI SHANG CHEMICAL Co., Ltd.
Poly-N-vinylacetamide (PNVA): weight average molecular weight of 31,000, manufactured by SHOWA DENKOK.K. (currently, RESONAC Holdings Corporation)
Polyvinyl alcohol (PVA): weight average molecular weight of 10,000, manufactured by JAPAN VAM & POVAL CO., LTD.
Polyethylene glycol (PEG): weight average molecular weight of 200, manufactured by DKS Co. Ltd.
Sorbitol: manufactured by FUJIFILM Wako Pure Chemical Corporation
Vinylpyrrolidone-N,N-dimethylaminoethyl methacrylic acid copolymer diethyl sulfate: weight average molecular weight of 150,000, manufactured by OSAKA ORGANIC CHEMICAL INDUSTRY LTD.

The symbol “−” in Table 1-2 below indicates that the relevant agent was not used. For example, Comparative Examples 1 and 9 to 11 are examples wherein a water-soluble agent was not used.

[Evaluation]

A surface of each object to be polished was polished using each of the polishing compositions prepared above under the following conditions. As each object to be polished, a silicon wafer (300 mm, blanket wafter; manufactured by Advanced Materials Technology, INC.) having a 3000 Å thick boron (B) (boron (B) content: 100 mass %) film (hereinafter, may also be simply referred to as “B film”) formed on a surface was prepared. When the pH of each polishing composition was measured before polishing, the result is as shown in Table 1-1 and Table 1-2.

(Polishing Apparatus and Polishing Conditions)
Polishing apparatus: manufactured by Ebara Corporation 300-mm CMP single-sided polisher FREX300E
Polishing pad: manufactured by NITTA DuPont Incorporated., polyurethane pad IC1010
Polishing pressure: 2.0 psi (1 psi=6894.76 Pa)
Rotational speed of platen: 90 rpm
Rotational speed of carrier: 91 rpm
Feed of polishing composition: free flowing
Feed rate of polishing composition: 250 ml/minute
Polishing time: 30 seconds

(Evaluation of Polishing Speed)

The thickness of the B film was measured before and after polishing using an optical film thickness measurement system (ASET-f5x: manufactured by KLA-Tencor Japan Ltd.). With the use of the thus found thicknesses, specifically, each value found by [(thickness before polishing)-(thickness after polishing)] was divided by the polishing time, thereby calculating the polishing speed for each object to be polished. The polishing speed of higher than 300 Å/min indicates that the composition tested can be practically used.

(Evaluation of the Number of Defects)

The number (Qty.) of 60 nm or more defects existing on the B film surface after polishing was measured using an optical inspection machine (wafer inspection system) “SURFSCAN SP5” manufactured by KLA-TENCOR in a measurement mode of DC mode. The number of defects of less than 700 indicates that the composition tested can be practically used.

The above evaluation results are shown in Table 1-1 and Table 1-2 below.

TABLE 1-1

| | Water-soluble additive | | Oxidizing agent | | Polishing | Polishing | Number |
|---|---|---|---|---|---|---|---|
| | | Concentration | Type | Content | composition | speed | of defects |
| | Type | (mass ppm) | | (mass %) | pH | [Å/min] | (Qty.) |
| Example 1 | Lauryldimethylamine oxide | 5 | H₂O₂ | 3.1 | 2.5 | 401 | 556 |
| Example 2 | Lauryldimethylamine oxide | 10 | H₂O₂ | 3.1 | 2.5 | 397 | 536 |
| Example 3 | Lauryldimethylamine oxide | 20 | H₂O₂ | 3.1 | 2.5 | 382 | 520 |
| Example 4 | Lauryldimethylamine oxide | 30 | H₂O₂ | 3.1 | 2.5 | 355 | 432 |
| Example 5 | n-Decyldimethylamine oxide | 20 | H₂O₂ | 3.1 | 2.5 | 388 | 612 |
| Example 6 | Myristyldimethylamine oxide | 20 | H₂O₂ | 3.1 | 2.5 | 370 | 508 |
| Example 7 | n-Octadecyldimethylamine oxide | 20 | H₂O₂ | 3.1 | 2.5 | 352 | 492 |
| Example 8 | Lauryldimethylamine oxide | 20 | H₂O₂ | 2 | 2.5 | 301 | 564 |
| Example 9 | Lauryldimethylamine oxide | 20 | H₂O₂ | 4 | 2.5 | 312 | 532 |
| Example | Lauryldimethylamine oxide | 20 | H₂O₂ | 3.1 | 3 | 385 | 580 |
| 10 | | | | | | | |
| Example | Lauryldimethylamine oxide | 20 | H₂O₂ | 3.1 | 3.5 | 358 | 604 |
| 11 | | | | | | | |
| Example | Lauryldimethylamine oxide | 20 | H₂O₂ | 3.1 | 4 | 332 | 637 |
| 12 | | | | | | | |

TABLE 1-2

| | Water-soluble additive | | Oxidizing agent | | Polishing | Polishing | Number of |
|---|---|---|---|---|---|---|---|
| | | Concentration | | Content | composition | speed | defects |
| | Type | (mass ppm) | Type | (mass %) | pH | [Å/min] | (Qty.) |
| Comparative | — | — | H₂O₂ | 3.1 | 2.5 | 362 | 899 |
| Example 1 | | | | | | | |
| Comparative | Lauryldimethylamine oxide | 50 | H₂O₂ | 3.1 | 2.5 | 145 | 2917 |
| Example 2 | | | | | | | |
| Comparative | Poly N-vinyl acetamide | 10 | H₂O₂ | 3.1 | 2.5 | 334 | 749 |
| Example 3 | | | | | | | |
| Comparative | Poly N-vinyl acetamide | 100 | H₂O₂ | 3.1 | 2.5 | 68 | 342 |
| Example 4 | | | | | | | |
| Comparative | Polyvinyl alcohol | 2,500 | H₂O₂ | 3.1 | 2.5 | 396 | 874 |
| Example 5 | | | | | | | |
| Comparative | Polyethylene glycol | 2,500 | H₂O₂ | 3.1 | 2.5 | 346 | 857 |
| Example 6 | | | | | | | |
| Comparative | Sorbitol | 2,500 | H₂O₂ | 3.1 | 2.5 | 368 | 919 |
| Example 7 | | | | | | | |
| Comparative | Vinylpyrrolidone-N,N-dimethylaminoethyl | 10 | H₂O₂ | 3.1 | 2.5 | Aggregation of | |
| Example 8 | methacrylic acid copolymer diethyl sulfate | | | | | abrasive grains | |
| Comparative | — | — | H₂O₂ | 0.47 | 2.5 | 189 | 1096 |
| Example 9 | | | | | | | |
| Comparative | — | — | H₂O₂ | 1.4 | 2.5 | 244 | 1040 |
| Example 10 | | | | | | | |
| Comparative | — | — | H₂O₂ | 4.7 | 2.5 | 291 | 886 |
| Example 11 | | | | | | | |
| Comparative | Lauryldimethylamine oxide | 20 | H₂O₂ | 3.1 | 5 | 296 | 701 |
| Example 12 | | | | | | | |
| Comparative | Lauryldimethylamine oxide | 20 | H₂O₂ | 3.1 | 7 | 46 | 330 |
| Example 13 | | | | | | | |

As is clear from Table 1-1 and Table 1-2 above, the use of the polishing compositions of Examples was found to reduce the number of defects on the B film surface due to polishing while polishing the B film at a high speed, compared with the use of the polishing compositions of Comparative Examples. Note that in the case of the polishing composition in Comparative Example 8, polishing could not be performed because of aggregated abrasive grains.

1. A polishing composition for use in polishing an object to be polished having a layer containing an element in group 13 of the periodic table in a content of 40 mass % or more, the polishing composition comprising:
a cationically modified silica, a trialkylamine oxide, and an oxidizing agent,
wherein a content of the trialkylamine oxide is 3 mass ppm or more and 40 mass ppm or less with respect to the total mass of the polishing composition, and
a pH is less than 5.

2. The polishing composition according to claim 1, wherein the pH is 2 or more and less than 4.

3. The polishing composition according to claim 1, wherein the trialkylamine oxide has at least one alkyl group having 8 or more and 20 or less carbon atoms.

4. The polishing composition according to claim 1, wherein the trialkylamine oxide has at least one selected from the group consisting of a n-decyl group, a lauryl group, a myristyl group, and a n-octadecyl group.

5. The polishing composition according to claim 1, wherein the trialkylamine oxide is at least one selected from the group consisting of a n-decyldimethylamine oxide, a lauryldimethylamine oxide, a myristyldimethylamine oxide, and a n-octadecyldimethylamine oxide.

6. The polishing composition according to claim 1, wherein a content of the oxidizing agent is 1 mass % or more and 5 mass % or less with respect to the total mass of the polishing composition.

7. The polishing composition according to claim 1, wherein the oxidizing agent is hydrogen peroxide.

8. The polishing composition according to claim 1, further comprising an antifungal agent.

9. A polishing method, comprising a step of polishing an object to be polished having a layer containing an element in group 13 of the periodic table in a content of 40 mass % or more using the polishing composition according to claim 1.

10. A method for producing a semiconductor substrate, comprising polishing a semiconductor substrate having a layer containing an element in group 13 of the periodic table in a content of 40 mass % or more by the polishing method according to claim 9.
